(19) United States
(12) Patent Application Publication
(10) Pub. No.: US 2009/0101984 A1
(43) Pub. Date: Apr. 23, 2009

(54) Semiconductor device having gate electrode including metal layer and method of manufacturing the same

(75) Inventors: Byung-hak Lee, Suwon-si (KR); Woong-hee Sohn, Seoul (KR); Jae-hwa Park, Yongin-si (KR); Gil-heyun Choi, Seoul (KR); Byung-hee Kim, Seoul (KR); Hee-sook Park, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/003,144

(22) Filed: Dec. 20, 2007

(30) Foreign Application Priority Data
Jan. 17, 2007 (KR) 10-2007-0005423

(51) Int. Cl. H01L 29/78; H01L 27/092

(52) U.S. Cl. 257/369; 257/410; 257/E29.255; 257/E27.062

(57) ABSTRACT

A semiconductor device may include a gate dielectric film on a semiconductor substrate and/or a gate electrode. The gate electrode may include a first metal film, a first metal silicide film, and/or a conductive polysilicon film sequentially stacked on the gate dielectric film.

### PRIORITY STATEMENT

This application claims the benefit of priority to Korean Patent Application No. 10-2007-0005423, filed on Jan. 17, 2007, in the Korean Intellectual Property Office, the entire contents of which are incorporated herein in their entirety by reference.

### BACKGROUND

1. Field

Example embodiments relate to a semiconductor device and/or a method of manufacturing the same, and for example, to a semiconductor device in which a gate electrode of a transistor which employs a high k film as a gate dielectric film includes a stacked structure of a metal film and a polysilicon film, and/or a method of manufacturing the semiconductor device.

2. Description of Related Art

As semiconductor devices have become more highly integrated, and as the size of features of metal oxide silicon field effect transistors (MOSFETs) has decreased, gate lengths and the length of channels formed below the gates have thereby been reduced. Accordingly, active research has been conducted into devices that employ a high k film as a gate dielectric film. A conventional device a material having a high k value. The material having the high k value may reduce leakage current between a gate electrode and a channel region and maintain a thinner equivalent oxide film thickness in order to increase the capacitance between a gate and a channel and improve the operating properties of the transistor.

However, if the gate electrode includes a polysilicon film in the MOSFET which uses a high k film as a gate dielectric film, a threshold voltage Vₜₕ is not controlled as desired due to a silicate which is formed at an interface between the polysilicon film and the high k film. In the case of PMOS transistors, if forming a gate electrode including a polysilicon film on the gate dielectric film which includes a high k film, a gate depletion phenomenon and a problem that a dopant is diffused from the gate electrode into the gate dielectric film occur. Thus, reliability of the device is deteriorated.

In order to overcome the above problem, a structure in which a metal film is interposed between a high k film and a polysilicon film has been suggested. However, in the gate electrode of a poly/single metal gate (PSMG) structure, as a result of thermal budget which is generated in a subsequent process, an insulating film, for example an insulating film having a Si—N bond, is formed, and an ohmic contact is not formed between the metal film and the polysilicon film. Accordingly, an interface resistance is suddenly increased and a problem due to a resistive-capacitive delay (RC delay) occurs.

### SUMMARY

Example embodiments may provide a semiconductor device having a gate electrode stacked structure which may reduce interface resistance between a metal and a polysilicon film in a gate electrode.

Example embodiments may provide a method of manufacturing a semiconductor device, which may reduce interface resistance between a metal film and a polysilicon film in a gate electrode.

According to an example embodiment, semiconductor device may include a gate dielectric film on a semiconductor substrate and/or a gate electrode comprising a first metal film, a first metal silicide film, and/or a conductive polysilicon film sequentially stacked on the gate dielectric film.

According to an example embodiment, the gate electrode may further include a first barrier film interposed between the first metal film and the first metal silicide film.

According to an example embodiment, the gate electrode may further include a second metal silicide film and second metal film sequentially stacked on the conductive polysilicon film. The gate electrode may further include a second barrier film interposed between the second metal silicide film and the second metal film.

According to an example embodiment, a semiconductor device may include a first MOS transistor including a first conductive type channel region formed in a semiconductor substrate, a first gate dielectric film on the first conductive type channel region, and/or a first gate electrode comprising a first metal film, a first metal silicide film, and/or a first conductive polysilicon film sequentially stacked on the first gate dielectric film. The semiconductor device may include a second MOS transistor including a second conductive type channel region formed in the semiconductor substrate, a second gate dielectric film formed on the second conductive type channel region, and/or a second gate electrode comprising a second conductive polysilicon film stacked on the second gate dielectric film.

According to an example embodiment, the first MOS transistor may be a PMOS transistor, and/or the second MOS transistor may be an NMOS transistor.

According to an example embodiment, the first gate electrode may further include a first barrier film interposed between the first metal film and the first metal silicide film.

According to an example embodiment, the first gate electrode may further include a second metal silicide film and a second metal film stacked sequentially on the first conductive polysilicon film, and/or the second gate electrode may further include a third metal silicide film and a third metal film stacked sequentially on the second conductive polysilicon film. The first gate electrode may further include a second barrier film interposed between the second metal silicide film and the second metal film, and/or the second gate electrode may further include a third barrier film interposed between the third metal silicide film and the third metal film.

According to an example embodiment, a method of manufacturing a semiconductor device may include forming a gate dielectric film on a semiconductor substrate, and/or forming a gate electrode comprising a first metal film, a first metal silicide film, and/or a conductive polysilicon film on the gate dielectric film.

According to an example embodiment, the method of manufacturing a semiconductor device may further include performing a reoxidation process to thermally treat the semiconductor substrate on which the gate electrode is formed at a temperature of about room temperature to 700° C. under an atmosphere which includes H₂ and O₂.

According to an example embodiment, the gate electrode may be formed to include a first barrier film interposed between the first metal film and the first metal silicide film. The gate electrode may be formed to include a second metal silicide film and a second metal film stacked sequentially on the conductive polysilicon film. The gate electrode may be formed to include a second barrier film interposed between the second metal silicide film and the second metal film.

According to an example embodiment, a method of manufacturing a semiconductor device may include preparing a semiconductor substrate having a first MOS region including a first conductive type channel and a second MOS region including a second conductive type channel opposite to the first conductive type. A first gate dielectric film and a second gate dielectric film may be formed in the first MOS region and the second MOS region, respectively. A first gate stacked structure and a second gate stacked structure may be formed on the first gate dielectric film and the second gate dielectric film, respectively. The forming the first gate stacked structure and the second gate stacked structure may include forming a first metal film on the first gate dielectric film and the second gate dielectric film, respectively, forming a first metal silicide film on the first metal film in the first MOS region and the second MOS region, removing the first metal film and the first metal silicide film in the second MOS region to leave the first metal film and the first metal silicide film only in the first MOS region, and/or respectively forming a conductive polysilicon film on the first metal silicide film in the first MOS region and on the second gate dielectric film in the second MOS region.

According to an example embodiment, the forming the first gate stacked structure and the second gate stacked structure may further include forming a second metal silicide film on the conductive polysilicon film, and/or forming a second metal film on the second metal silicide film.

According to an example embodiment, the forming the first gate stacked structure and the second gate stacked structure may further include forming a second barrier film on the second metal silicide film after forming the second silicide film. The second metal film may be formed on the second barrier film.

According to an example embodiment, the method of manufacturing a semiconductor device may further include sequentially patterning the first gate stacked structure and the first gate dielectric film to form a first gate line pattern. The second gate stacked structure and the second gate dielectric film may be sequentially patterned to form a second gate line pattern. A reoxidation process to thermally treat the semiconductor substrate on which the first gate line pattern and the second gate line pattern are formed may be performed at temperature range of room temperature to 700° C. under an atmosphere which includes H₂ and O₂.

According to an example embodiment, a contact resistance property in the gate line pattern may be improved remarkably by interposing the first metal silicide film, which may be an ohmic layer, between the first metal film, which is on the gate dielectric film, and the conductive polysilicon film, which is formed on the first metal film. By lowering the process temperature below 700° C. in the reoxidation process, which may be performed after forming the gate line pattern, the formation of an undesired oxide formed due to the oxidation of the metal silicide film may be reduced. Accordingly, the contact resistance property in the gate line pattern may be improved.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1A through FIG. 1H are cross-sectional views illustrating a method of manufacturing a semiconductor device according to an example embodiment;

FIG. 2 is an example graph comparing contact resistance according to current density of a semiconductor device having a gate line pattern structure according to an example embodiment to a comparative example; and

FIGS. 3A, 3B, and 3C are transmission electron microscope (TEM) images showing an effect obtained based upon a process temperature in a re-oxidation process in the method of manufacturing the semiconductor device according to an example embodiment.

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

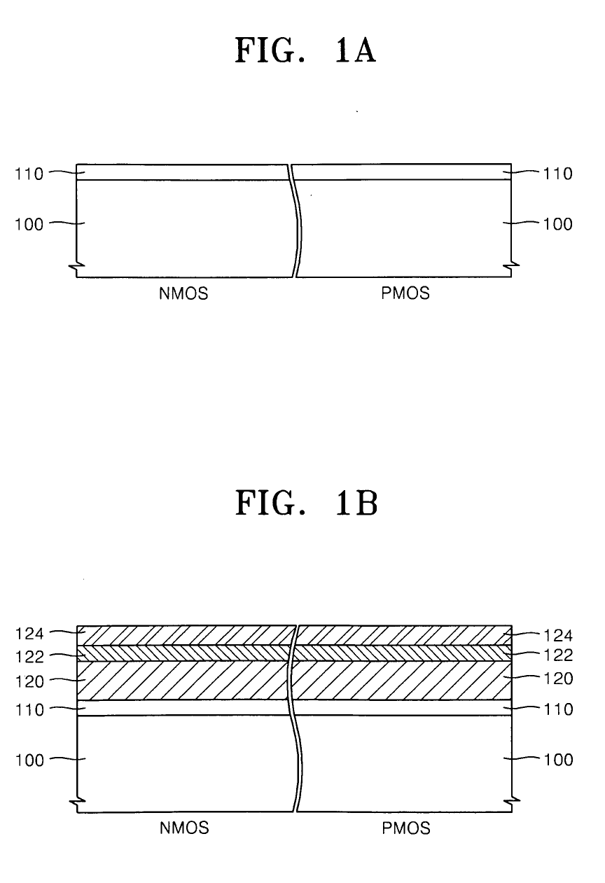

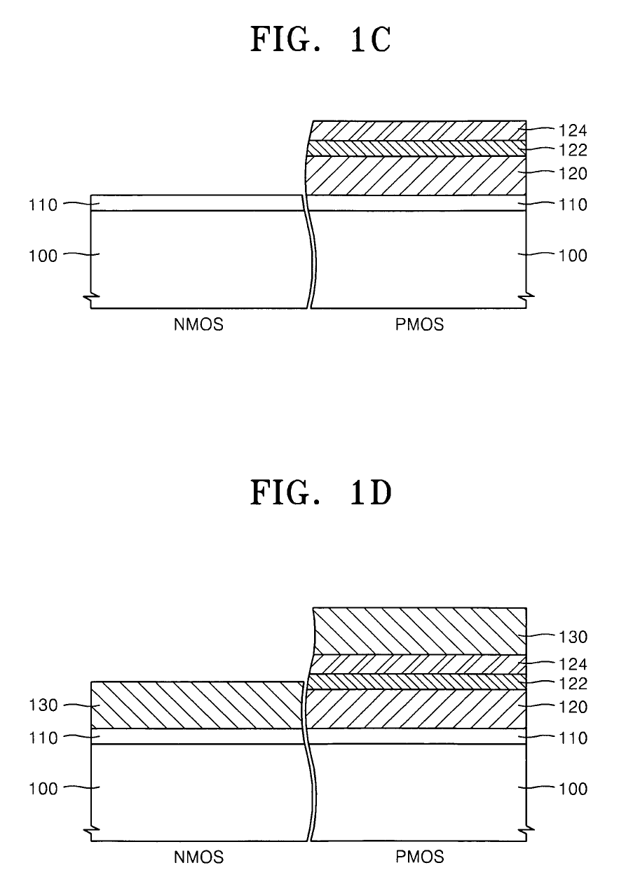

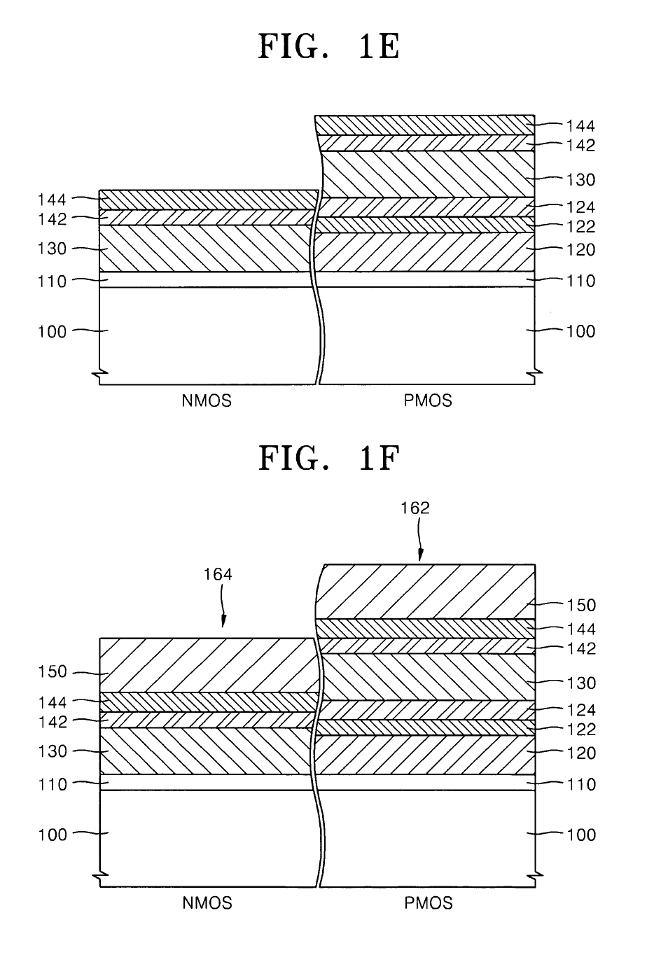

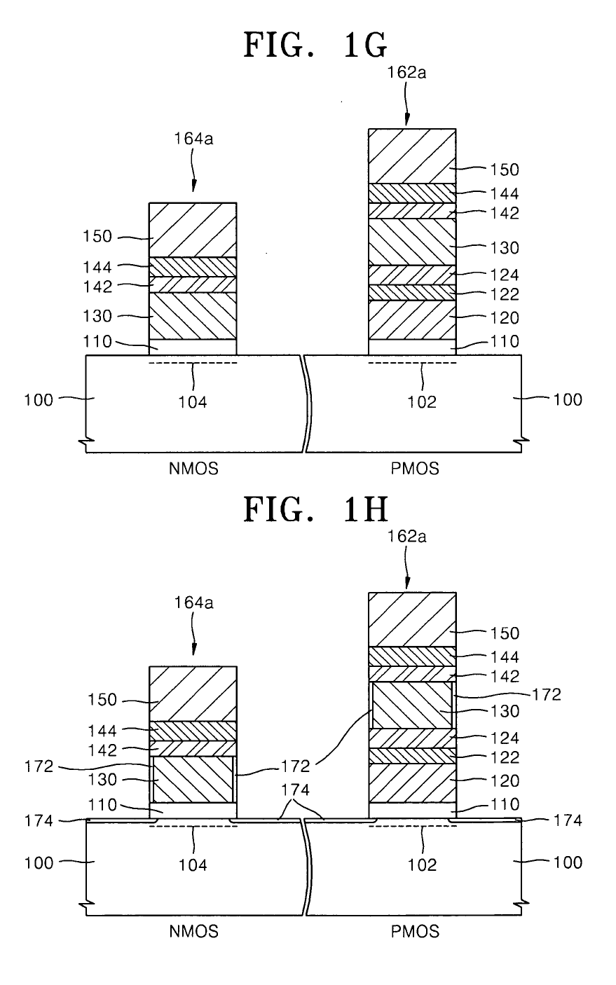

FIG. 1A through FIG. 1H are cross-sectional views illustrating a method of manufacturing a semiconductor device according to an example embodiment.

Referring to FIG. 1A, a semiconductor substrate 100, for example, a silicon substrate may be prepared. The semiconductor substrate 100 may include a PMOS region (e.g., as indicated “PMOS” in the figures) in which a p-channel MOS transistor may be formed and/or a NMOS region (e.g., as indicated “NMOS” in the figures) in which an n-channel MOS transistor may be formed.

A gate dielectric film 110 comprising a high k film may be formed in the PMOS region and/or the NMOS region on the semiconductor substrate 100.

The gate dielectric film 110 may include a high k film having a higher dielectric constant than that of a silicon oxide film. For example, the gate dielectric film 110 may comprise at least one material selected from a group including HfO₂, Al₂O₃, ZrO₂, Hf silicate, Al silicate, and Zr silicate. For example, the gate dielectric film 110 may comprise at least one material selected from a group consisting of HfO₂, Al₂O₃, ZrO₂, Hf silicate, Al silicate, and Zr silicate. The gate dielectric film 110 may be formed to have an appropriate thickness in a range of approximately 0.2-50 Å depending on a desired thickness, or alternatively, the type of device intended to be formed.

Referring to FIG. 1B, a first metal film 120, a first barrier film 122, and/or a first metal silicide film 124 may be formed, e.g., formed sequentially, on the gate dielectric film 110 in the PMOS region and the NMOS region.

The first metal film 120 may include of a p-type metal of which a work function is above 4.6 eV. For example, the first metal film 120 may include any one material selected from a group including tungsten nitride (WNₓ), molybdenum nitride (MoNₓ), tungsten carbide nitride (WCₓN_{y}), RuO₂, Ni, Ir, and Pt. For example, the first metal film 120 may be composed of any one material selected from a group consisting of tungsten nitride (WNₓ), molybdenum nitride (MoNₓ), tungsten carbide nitride (WCₓN_{y}), RuO₂, Ni, Ir, and Pt. The first metal film 120 may be formed to have a thickness selected from a range of approximately 1-200 Å depending on a desired thickness, or alternatively, the size of the intended device.

The first barrier film 122 may include a metal nitride which is not decomposed even at a temperature greater than approximately 600° C. For example, the first barrier film 122 may include TiN or TaN. The barrier film 122 may be formed using physical vapor deposition (PVD), chemical vapor deposition (CVD), or atomic layer deposition (ALD) and/or may be formed to have a thickness of approximately 30-300 Å. In forming the first barrier film 122, the first barrier film 122 may be formed of N-rich metal nitride having a higher N content than a metal (M) content according to stoichiometry, by performing a deposition process under conditions in which a supply of nitrogen atoms (N) is greater than a supply of metal atoms (M). However, the barrier film 122 may not be included.

The first metal silicide film 124 may be formed such that an ohmic contact is made between the first metal film 120 and a polysilicon film which may be formed in a subsequent process. The first metal silicide film 124 may include at least one metal silicide selected from a group including tungsten silicide, molybdenium silicide, titanium silicide, tantalum silicide, and cobalt silicide. The first metal silicide film 124 may consist of at least one metal silicide selected from a group consisting of tungsten silicide, molybdenium silicide, titanium silicide, tantalum silicide, and cobalt silicide. The first metal silicide film 124 may be formed using PVD, CVD, or ALD, and/or may be formed to have a thickness of approximately 10-200 Å.

Referring to FIG. 1C, portions of the first metal film 120, the first barrier film 122, and/or the first metal silicide film 124 in the NMOS region may be selectively removed, thus leaving the first metal film 120, the first barrier film 122, and/or the first metal silicide film 124 only in the PMOS region. Accordingly, a process in which the first metal film 120, the first barrier film 122, and/or the first metal silicide film 124 are etched and removed in the NMOS region by covering the PMOS region with a photoresist pattern (not shown) such that the NMOS region is exposed may be used.

Referring to FIG. 1D, a conductive polysilicon film 130 may be formed on the first metal silicide film 124, which is in the PMOS region, and/or on the exposed section of the gate dielectric film 110 in the NMOS region. The conductive polysilicon film 130 may include a polysilicon material into which an n-type impurity, for example phosphorus (P) or arsenic (As) is doped. The conductive polysilicon film 130 may consist of a polysilicon material into which an n-type impurity, for example phosphorus (P) or arsenic (As) is doped.

Referring to FIG. 1E, a second metal silicide film 142 and/or a second barrier film 144 may be formed on the conductive polysilicon film 130 in the PMOS region and the NMOS region.

The second metal silicide film 142 and the second barrier film 144 may be similar to the first metal silicide film 124 and the first barrier film 122, respectively, which were described with reference to FIG. 1B, and therefore, detailed descriptions thereof are omitted. The second barrier film 144 may not be included.

Referring to FIG. 1F, a second metal film 150 may be formed on the second barrier film 144 in the PMOS region and the NMOS region. The second metal film 150 may include W or Mo. The second metal film 150 may be formed using PVD, CVD, or ALD, and/or may be formed to have a thickness of approximately 100-1500 Å.

Accordingly, a first gate stacked structure 162 in which portions of the first metal film 120, the first barrier film 122, the first metal silicide film 124, the conductive polysilicon film 130, the second metal silicide film 142, the second barrier film 144, and/or the second metal film 150 are stacked, e.g., sequentially stacked, on the gate dielectric film 110 may be formed in the PMOS region. A second gate stacked structure 164 in which portions of the conductive polysilicon film 130, the second metal silicide film 142, the second barrier film 144, and/or the second metal film 150 are stacked, e.g., sequentially stacked, on the gate dielectric film 110 may be formed in the NMOS region.

Referring to FIG. 1G, the gate dielectric film 110, the first gate stacked structure 162, and/or the second gate stacked structure 164 may be patterned in the PMOS region and the NMOS region. As a result, a first gate line pattern 162a which comprises a PMOS transistor may be formed on a p-type channel region 102 of the semiconductor substrate 100 in the PMOS region, and/or a second gate line pattern 164a comprising an NMOS transistor may be formed on an n-type channel region 104 of the semiconductor substrate 100 in the NMOS region.

The first gate line pattern 162a, which is formed in the PMOS region, may have a structure in which portions of the first metal film 120, the first barrier film 122, the first metal silicide film 124, the conductive polysilicon film 130, the second metal silicide film 142, the second barrier film 144, and/or the second metal film 150 are stacked, e.g., sequentially stacked, on the portion of the gate dielectric film 110 in the PMOS region, and/or the second gate line pattern 164a, which is formed in the NMOS region, may have a structure in which portions of the conductive polysilicon film 130, the second metal silicide film 142, the second barrier film 144, and/or the second metal film 150 are stacked, e.g., sequentially stacked, on the portion of the gate dielectric film 110 in the NMOS region. As described above, a CMOS transistor which includes gate electrodes having different work functions in the PMOS transistor and the NMOS transistor may be obtained by employing a metal gate structure having a different gate stacked structure based on a channel type.

Referring to FIG. 1H, a reoxidation process by which the semiconductor substrate 100, on which the first gate line pattern 162a and the second gate line pattern 164a are formed, may be thermally treated at a temperature range of about room temperature −700° C. under an atmosphere comprising H₂ and O₂ may be performed. The reoxidation may be performed under an atmosphere into which H₂ and O₂ are supplied at a H₂/O₂ flow rate selected from the range of 2/50 through 50/2. As a result, oxide films 172 and 174 may be formed on sidewalls of the conductive polysilicon film 130 and/or an exposed surface of the semiconductor substrate 100, and/or a damaged surface of the semiconductor substrate 100, which may be damaged during the etching process for forming the first gate line pattern 162a and the second gate line pattern 164a, may be cured.

In performing the reoxidation process, for example, H₂, O₂ and Ar gas may be supplied onto the semiconductor substrate 100 to generate oxygen radicals O* and hydroxyl radicals OH* by a plasma power, such that the sidewalls of the conductive polysilicon film 130 and/or the exposed surface of the semiconductor substrate 100 may be oxidized. By lowering a process temperature of the reoxidation process below about 700° C., the formation of an oxide, for example SiOx, may be reduced between the first barrier film 122 and the first metal silicide film 124, and/or between the second metal silicide film 142 and the second barrier film 144 by oxidation of the first and second metal silicide films 122 and 142. An interface resistance between the first gate line pattern 162a and the second gate line pattern 164a may be reduced by reducing the formation of an undesired oxide between the first barrier film 122 and the first metal silicide film 124, and/or between the second metal silicide film 142 and the second barrier film 144, as described above.

In the first gate line pattern 162a illustrated in FIG. 1H, the first metal silicide film 124 may be interposed between the first metal film 120 and the conductive polysilicon film 130. Accordingly, even if a metal nitride which includes the first metal film 120 in the PMOS region is decomposed into a metal and nitrogen atoms due to subsequent thermal budget, there may be no risk that the insulating film having a undesired Si—N bond is formed by the reaction of the decomposed nitrogen atoms with Si atoms of the conductive polysilicon film 130. Accordingly, the contact resistance in the first gate line pattern 162a may be reduced.

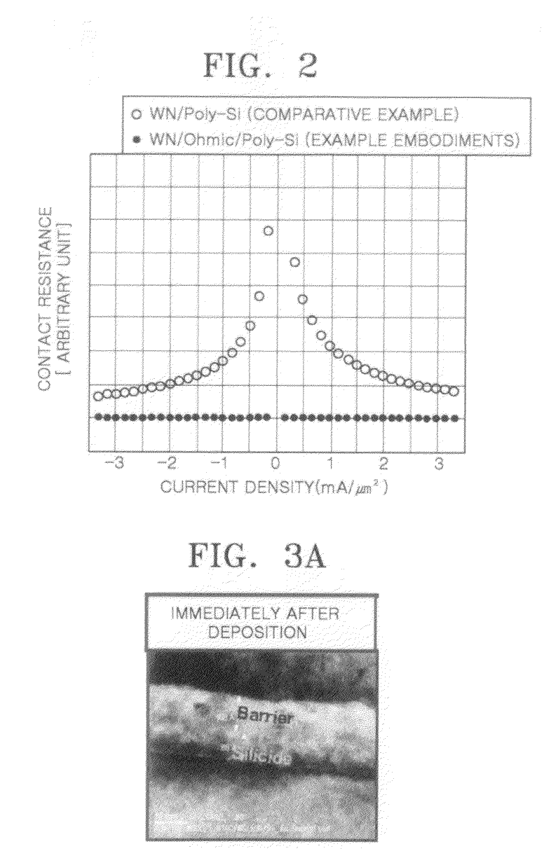

FIG. 2 is an example graph illustrating contact resistance according to current density of a semiconductor device having a gate line pattern structure according to an example embodiment compared to a comparative example.

In order to evaluate the interface resistance change of a semiconductor device having a gate line pattern structure according to an example embodiment, a gate line pattern (as indicated by “WN/Ohmic/Poly-Si”) having a structure in which a WN film (50 Å in thickness), a tungsten silicide film (50 Å in thickness) serving as an ohmic layer, and a conductive polysilicon film are stacked on a gate dielectric film from the semiconductor substrate is formed, and the contact resistance change in an interface between the WN film and the conductive polysilicon film in the structure is measured, as indicated by the filled in dot symbols in FIG. 2.

As a comparative example, a gate line pattern (as indicated by “WN/Poly-Si”) having the same structure as that of an example embodiment, is formed, excepting for forming a tungsten silicide film between a WN film and a conductive polysilicon film, and the contact resistance change in an interface between the WN film and the conductive polysilicon film in the structure is measured, as indicated by the empty dot symbols ◯ in FIG. 2.

According to the graph of FIG. 2, the contact resistance at the interface may be reduced by forming an ohmic layer which includes the tungsten silicide film between the WN film and the conductive polysilicon film.

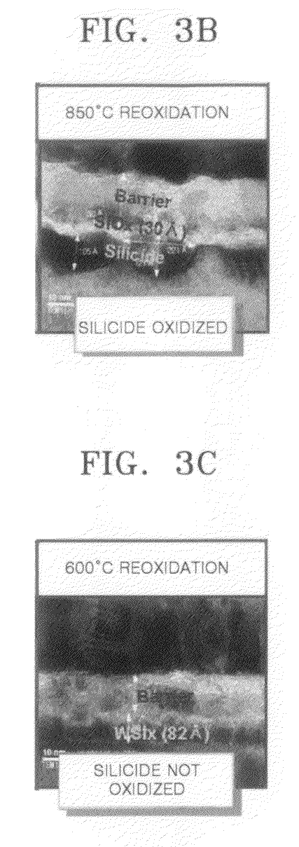

FIGS. 3A, 3B, and 3C are transmission electron microscope (TEM) images showing an effect obtained based upon a process temperature in the reoxidation process which is described with reference to FIG. 1H in the method of manufacturing the semiconductor device according to an example embodiment.

For example, a gate stacked structure comprising a WN film which is a p-type metal film, a TiN barrier film, a tungsten silicide film which is an ohmic layer, which correspond to the first metal film 120, the first barrier film 122, the first metal silicide film 124, and the conductive polysilicon film 130, respectively, as illustrated in FIG. 1H is formed. The TEM image in FIG. 3A shows a cross-sectional shape immediately after the deposition of the gate stacked structure. The TEM image in FIG. 3B shows a cross-sectional shape obtained after performing the reoxidation process of the gate stacked structure at a temperature of 850° C., as described with reference to FIG. 1H. The TEM image in FIG. 3C shows a cross-sectional shape obtained after performing the reoxidation process of the gate stacked structure at a temperature of 600° C., as described with reference to FIG. 1H.

As can be seen from the TEM image of FIG. 3B, if the reoxidation process is performed at a process temperature of 850° C., which is a relatively higher temperature, the tungsten silicide film which is the ohmic layer is oxidized and an undesired oxide film (SiOₓ) is formed between the WN film which is a p-type metal film and the polysilicon film, such that the contact resistance is increased. On the other hand, as can be seen from the TEM image of FIG. 3C, if the reoxidation process is performed at a temperature of 600° C., which is a relatively lower temperature, the oxidation of the ohmic layer is suppressed such that the oxide film is not formed between the WN film and the polysilicon film.

In the semiconductor device according to an example embodiment, the first silicide metal film as an ohmic layer may be interposed between the first metal film formed on the gate dielectric film and the conductive polysilicon film formed on the first metal film in the gate line pattern, and for example, in the gate line pattern including the PMOS transistor. Accordingly, even if a metal nitride including the first metal film in the PMOS region is decomposed into metal and nitrogen atoms due to a thermal budget, there may be no risk of the decomposed nitrogen atoms reacting with Si atoms of the conductive polysilicon film, such that an insulating film having undesired Si—N bond may be formed. Accordingly, the contact resistance in the first gate line pattern may be reduced. Formation of Si—N bond may be more effectively reduced on the first metal film by interposing the first barrier film between the first metal film and the first metal silicide film which may be an ohmic layer. In the semiconductor device according to an example embodiment, the effect which is obtained by forming the second metal silicide film and the second barrier film between the conductive polysilicon film and the second metal film, which is formed on the conductive polysilicon film in the gate line pattern in each of the PMOS region and the NMOS region, may be the same as the effect which is obtained by forming the first metal silicide film and the first barrier film in the PMOS region, as described above. Therefore, the contact resistance in the gate line pattern may be reduced in the semiconductor device according to an example embodiment.

In the semiconductor device according to an example embodiment, by lowering the process temperature below about 700° C. in the reoxidation process, which may be performed after forming the gate line pattern, the formation of an undesired oxide may be reduced due to the oxidation of the metal silicide film. Accordingly, the contact resistance in the gate line pattern may be reduced using the method of manufacturing the semiconductor device according to an example embodiment.

Although example embodiments have been shown and described in this specification and figures, it would be appreciated by those skilled in the art that changes may be made to the illustrated and/or described example embodiments without departing from their principles and spirit.

1. A semiconductor device, comprising:
a gate dielectric film on a semiconductor substrate; and
a gate electrode comprising a first metal film, a first metal silicide film, and a conductive polysilicon film sequentially stacked on the gate dielectric film.

2. The semiconductor device of claim 1, wherein the first metal film includes at least one material selected from a group including tungsten nitride (WNₓ), molybdenium nitride (MoNₓ), tungsten carbide nitride (WCₓN_{y}), RuO₂, Ni, Ir, and Pt.

3. The semiconductor device of claim 1, wherein the first metal silicide film includes at least one metal silicide selected from a group including tungsten silicide, molybdenium silicide, titanium silicide, tantalum silicide, and cobalt silicide.

4. The semiconductor device of claim 1, wherein the gate dielectric film includes at least one material selected from a group including HfO₂, Al₂O₃, ZrO₂, Hf silicate, Al silicate, and Zr silicate.

5. The semiconductor device of claim 1, wherein the gate electrode further comprises a first barrier film interposed between the first metal film and the first metal silicide film.

6. The semiconductor device of claim 5, wherein the first barrier film includes a metal nitride.

7. The semiconductor device of claim 5, wherein the first barrier film includes at least one of TiN and TaN.

8. The semiconductor device of claim 1, wherein the gate electrode further comprises a second metal silicide film and a second metal film sequentially stacked on the conductive polysilicon film.

9. The semiconductor device of claim 8, wherein the gate electrode further comprises a second barrier film interposed between the second metal silicide film and the second metal film.

10. The semiconductor device of claim 8, wherein the second barrier film includes at least one of TiN and TaN.

11. The semiconductor device of claim 8, wherein the second metal silicide film includes at least one metal silicide selected from a group including tungsten silicide, molybdenium silicide, titanium silicide, tantalum silicide, and cobalt silicide.

12. The semiconductor device of claim 8, wherein the second metal film includes at least one of W and Mo.

13. A semiconductor device, comprising:
a first MOS transistor including a first conductive type channel region in a semiconductor substrate, a first gate dielectric film on the first conductive type channel region, and a first gate electrode including a first metal film, a first metal silicide film, and a first conductive polysilicon film sequentially stacked on the first gate dielectric film; and
a second MOS transistor including a second conductive type channel region in the semiconductor substrate, a second gate dielectric film on the second conductive type channel region, and a second gate electrode including a second conductive polysilicon film stacked on the second gate dielectric film.

14. The semiconductor device of claim 13, wherein
the first MOS transistor is a PMOS transistor, and
the second MOS transistor is an NMOS transistor.

15. The semiconductor device of claim 14, wherein the first metal film includes at least one material selected from a group including tungsten nitride (WNₓ), molybdenium nitride (MoNₓ), tungsten carbide nitride (WCₓN_{y}), RuO₂, Ni, Ir, and Pt.

16. The semiconductor device of claim 13, wherein the first gate dielectric film and the second gate dielectric film have a same structure.

17. The semiconductor device of claim 13, wherein the first gate electrode further comprises a first barrier film interposed between the first metal film and the first metal silicide film.

18. The semiconductor device of claim 13, wherein
the first gate electrode further comprises a second metal silicide film and a second metal film stacked sequentially on the first conductive polysilicon film; and
the second gate electrode further comprises a third metal silicide film and a third metal film stacked sequentially on the second conductive polysilicon film.

19. The semiconductor device of claim 18, wherein each of the second metal silicide film and the third metal silicide film includes at least one metal silicide selected from a group including tungsten silicide, molybdenium silicide, titanium silicide, tantalum silicide, and cobalt silicide.

20. The semiconductor device of claim 13, wherein
the first gate electrode further comprises a second barrier film interposed between the second metal silicide film and the second metal film; and
the second gate electrode further comprises a third barrier film interposed between the third metal silicide film and the third metal film.
